(19) United States
(12) Patent Application Publication
(10) Pub. No.: US 2023/0386793 A1
(43) Pub. Date: Nov. 30, 2023

(54) ETCHING METHOD AND ETCHING APPARATUS

(71) Applicant: HITACHI HIGH-TECH CORPORATION, Minato-ku, Tokyo (JP)

(72) Inventors: Yosuke KUROSAKI, Tokyo (JP); Kenji MAEDA, Tokyo (JP); Hiroto OTAKE, Tokyo (JP)

(21) Appl. No.: 17/912,943

(22) PCT Filed: Feb. 19, 2021
(86) PCT No.: PCT/JP2021/006253

§ 371 Date: Sep. 20, 2022

(51) Int. Cl. H01J 37/32; H01L 21/311

(52) U.S. Cl. CPC H01J 37/3244; H01L 21/31116; H01J 37/32834; H01J 2237/334

(57) ABSTRACT

Provided are an etching method and an etching apparatus that allow etching processing of a silicon nitride film to be performed at a high etching rate, while maintaining high processing dimension controllability at an atomic layer level, high uniformity in a pattern depth direction, and high selectivity to silicon dioxide. An etching method includes a first step of supplying an etchant containing hydrogen to a sample having a surface at which a silicon nitride is exposed to form a first modified layer in which the hydrogen is bonded to the silicon nitride, a second step of supplying an etchant containing fluorine to the sample to form, over the first modified layer, a second modified layer in which the hydrogen and the fluorine are bonded to the silicon nitride, and a third step of irradiating the first modified layer and the second modified layer with an infrared ray.

### TECHNICAL FIELD

The present invention relates to an etching method and an etching apparatus.

### BACKGROUND ART

With prevalence of mobile devices such as a smartphone and advance of a cloud technology, high integration of semiconductor devices has been promoted around the world, and there is a strong demand for an accompanying highly difficult semiconductor processing technology. For example, with regard to a memory semiconductor, the limits of planar circuit miniaturization in a NAND flash memory are beginning to appear and, in view of this, mass production has been applied to a memory using a three-dimensional multi-layer technology. Meanwhile, with regard to a logic semiconductor, a fin type FET (Field Effect Transistor) having a three-dimensional structure is becoming mainstream and, as a technology that goes beyond that, a GAA (Gate All Around) type semiconductor technology has been actively developed.

As such three-dimensional implementation and miniaturization of an element structure is simultaneously and concurrently pursued, in a device fabrication process, there have been demands for high-precision processing dimensional precision, a high selectivity of a material to be etched to another material, a high etching rate that implements a high throughput, high-precision isotropic etching, and the like. Particularly for the isotropic etching, a wet etching technique using a chemical liquid such as etching of silicon dioxide using a hydrofluoric acid or etching of silicon nitride using a hot phosphoric acid has been used widely. Meanwhile, with increasing miniaturization of devices, a pattern collapse due to a surface tension of the chemical liquid has presented a problem, and a dry etching technique less suffering from such a problem is in strong demand.

The silicon nitride is a material widely used for spacers or the like in semiconductor devices. As a conventional dry etching technique for a nitride not using a chemical liquid, an ALE (Atomic Layer Etching) method for titanium nitride using a fluorocarbon plasma and infrared irradiation is disclosed in Patent Literature 1. Meanwhile, an etching method that uses vibrational excitation of hydrogen fluoride (referred to as HF) to be able to ensure a high selectivity of silicon nitride to silicon dioxide is disclosed in each of Nonpatent Literatures 1 and 2.

The technology in each of Nonpatent Literatures 1 and 2 applies the vibrationally excited HF to the silicon nitride to reduce activation energy for bond breaking between nitrogen and silicon and thereby etch the silicon nitride. For the silicon dioxide, the vibration energy of oxygen and hydrogen is substantially equal to the vibration energy of fluorine and hydrogen, and accordingly resonance occurs and the activation energy does not decrease. In addition, since activation energy for disassociation is also low, adsorption of the HF scarcely occurs and, consequently, the silicon nitride is etched selectively to the silicon dioxide. Therefore, the technology may become an extremely important technology not only in trimming of the silicon nitride or the like, but also in a step of selectively etching the silicon nitride in a multilayer film including the silicon nitride and the silicon dioxide or the like.

### CITATION LIST

### Patent Literature

Patent Literature 1: Japanese Unexamined Patent Application Publication No. 2018-41886 Nonpatent Literatures
Nonpatent Literature 1: V. Volynets, Y. Barsukov, G. Kim, J-E. Jung, S. K. Nam, K. Han, S. Huang, and M. J. Kushner, “Highly selective Si₃N₄/SiO₂ etching using an NF₃/N₂/O₂/H₂ remote plasma.
I. Plasma source and critical fluxes”, Journal of Vacuum Science & Technology A Volume 38 02300 7 (2020), (URL: https://doi.org/10.1116/1.5125568)
Nonpatent Literature 2: J-E. Jung, Y. Barsukov, V. Volynets G. Kim, S. K. Nam, K. Han, S. Huang, and M. J. Kushner, “Highly selective Si₃N₄/SiO₂ etching using an NF₃/N₂/O₂/H₂ remote plasma.
II. Surface reaction mechanism”, Journal of Vacuum Science & Technology A Volume 38 023008 (2020), (URL: https://doi.org/10.1116/1.5125569)

### SUMMARY OF INVENTION

### Technical Problem

In Nonpatent Literatures 1 and 2, the vibrationally excited HF is supplied to the silicon nitride by using a plasma of a NF₃/N₂/O₂/H₂ gas mixture. However, in general, a lifetime of the vibrationally excited HF is only about a microsecond or shorter, and a hydrogen plasma consumes generated fluoride ions and fluoride radicals under a scavenger effect. As a result, it is difficult for the technology described above to supply a sufficient amount of the vibrationally excited HF to a substrate region. In addition, from a viewpoint of processability, a higher density and a large number of stacked layers in a device cause a supply rate-controlled state where a sufficient etchant cannot be supplied to details such as a bottom portion of a hole, and consequently it becomes difficult to implement uniform etching irrespective of location.

An object of the present invention is to provide an etching method and an etching apparatus that allow etching processing of a silicon nitride film to be performed at a high etching rate, while maintaining high processing dimension controllability at an atomic layer level, high uniformity in a pattern depth direction, and high selectivity to silicon dioxide.

### Solution to Problem

To solve the problem described above, an etching method according to a representative aspect of the present invention is implemented by including: a first step of supplying an etchant containing hydrogen to a sample having a surface at which a silicon nitride is exposed to form a first modified layer in which the hydrogen is bonded to the silicon nitride; a second step of supplying an etchant containing fluorine to the sample to form, over the first modified layer, a second modified layer in which the hydrogen and the fluorine are bonded to the silicon nitride; and a third step of irradiating the first modified layer and the second modified layer with an infrared ray.

An etching method according to another representative aspect of the present invention is implemented by including: a fourth step of supplying an etchant containing a hydrogen fluoride to a sample having a surface at which a silicon nitride is exposed to form a first modified layer in which hydrogen is bonded to the silicon nitride and a second modified layer in which the hydrogen and fluorine are bonded to the silicon nitride; and a fifth step of irradiating the first modified layer and the second modified layer with an infrared ray.

### Advantageous Effect of Invention

According to the present invention, it is possible to provide an etching method and an etching apparatus that allow etching processing of a silicon nitride film to be performed at a high etching rate, while maintaining high processing dimension controllability at an atomic layer level, high uniformity in a pattern depth direction, and high selectivity to silicon dioxide. Problems, configurations, and effects other than those described above will be made apparent by the following description of an embodiment.

### BRIEF DESCRIPTION OF DRAWINGS

FIG. 1 is a cross-sectional view illustrating a schematic configuration of an etching apparatus according to a first embodiment of the present invention;

FIG. 2 is a schematic view illustrating an example of a processing procedure of an etching method according to the first embodiment of the present invention;

FIG. 3 is a diagram illustrating an etching rate of a silicon nitride film and a silicon dioxide film which is different when Steps S102 to S104 are present and when Steps S102 to S104 are absent in the etching method according to the first embodiment of the present invention;

FIG. 4 is a diagram illustrating dependency of an etching rate of a silicon nitride film on a time during which a H₂ plasma is applied in Step S102 in the etching method according to the first embodiment of the present invention;

FIG. 5 is a diagram illustrating dependency of the etching rate of the silicon nitride film on a time during which a SF₆ plasma is applied in Step S103 in the etching method according to the first embodiment of the present invention;

FIG. 6 is a diagram illustrating dependency of etching rates of a silicon nitride film and a silicon dioxide film on a gas species in Step S102 in the etching method according to the first embodiment of the present invention;

FIG. 7 is a diagram illustrating dependency of the etching rates of the silicon nitride film and the silicon dioxide film on a gas species in Step S103 in the etching method according to the first embodiment of the present invention;

FIG. 8 is a cross-sectional view of a wafer in each of steps illustrating an example of a processing procedure when a multilayer structure including a silicon nitride film is processed using the etching method according to the first embodiment of the present invention;

FIG. 9 is a schematic view illustrating an example of a processing procedure of an etching method according to a second embodiment of the present invention;

FIG. 10 is a diagram illustrating an etching rate of a silicon nitride film and a silicon dioxide film which is different when Step S107 is present and when Step S107 is absent in the etching method according to the second embodiment of the present invention;

FIG. 11 is a cross-sectional view of a wafer in each of steps illustrating an example of a processing procedure when a multilayer structure including a silicon nitride film is processed using the etching method according to the second embodiment of the present invention; and

FIG. 12 is a cross-sectional view of a wafer in each of steps illustrating an example of a processing procedure when a structure including a silicon nitride film is processed using the etching method according to the second embodiment of the present invention.

### DESCRIPTION OF EMBODIMENTS

The present inventors have attempted to etch silicon nitride by using various gases. As a result, the present inventors have found that a supply of an etchant containing hydrogen to the silicon nitride results in formation of a modified layer containing hydrogen in a surface thereof, a supply of an etchant containing fluorine to the silicon nitride results in formation of a modified layer containing hydrogen and fluorine in an uppermost surface, an amount of generation of the modified layers has self-saturation, and the modified layers are removed by infrared irradiation.

The present invention has been achieved on the basis of such new findings. According to the present invention, the modified layers are formed by supplying hydrogen and fluorine in the etchants to the surface of the silicon nitride, and the surface modified layers are irradiated with an infrared ray to be removed. By repeating the formation and the removal, it is possible to etch an intended amount of the silicon nitride.

In addition, with an etching technique of the present invention, instead of supplying vibrationally excited HF to over the silicon nitride, the modified layers containing hydrogen and fluorine are formed in advance, and then the modified layer are irradiated with the infrared ray to generate the vibrationally excited HF. Therefore, it is possible to efficiently supply a sufficient amount of the vibrationally excited HF to the silicon nitride. An energy for the vibrational excitation of the HF mentioned herein corresponds to an about 2.4 μm wavelength range and, accordingly, it is possible to cause the vibrational excitation by irradiation with the infrared ray including the wavelength range mentioned above. A characteristic feature of the present invention is that, immediately below the modified layer containing hydrogen and fluorine, the modified layer containing only hydrogen is placed.

In general, the vibrationally excited HF is generated on the basis of a chemical formula H₂+F→HF*+H (where HF* represents the vibrationally excited HF), and therefore it is required to supply excessive hydrogen to fluorine. This is because a reaction factor is larger than that of a matching reaction given by F₂+H→HF*+F. Accordingly, by placing the modified layer containing only hydrogen, it is possible to more efficiently generate the vibrationally excited HF.

In addition, according to the etching technique of the present invention, processing having self-saturation is performed, and accordingly uniformity of an etching amount in each of a wafer in-plane direction and a pattern depth direction increases. Moreover, since the etching amount is determined by a depth of the modified layers and the number of times cycle processing was repeated, it is possible to precisely control the etching amount.

The following will describe embodiments of the present invention in detail with reference to the drawings. Note that, throughout all the drawings for illustrating the embodiments, parts having the same functions are given the same reference sings, and a repeated description thereof is omitted. Note that, for improved clarity of illustration of a configuration, even a plan view may be hatched.

### First Embodiment

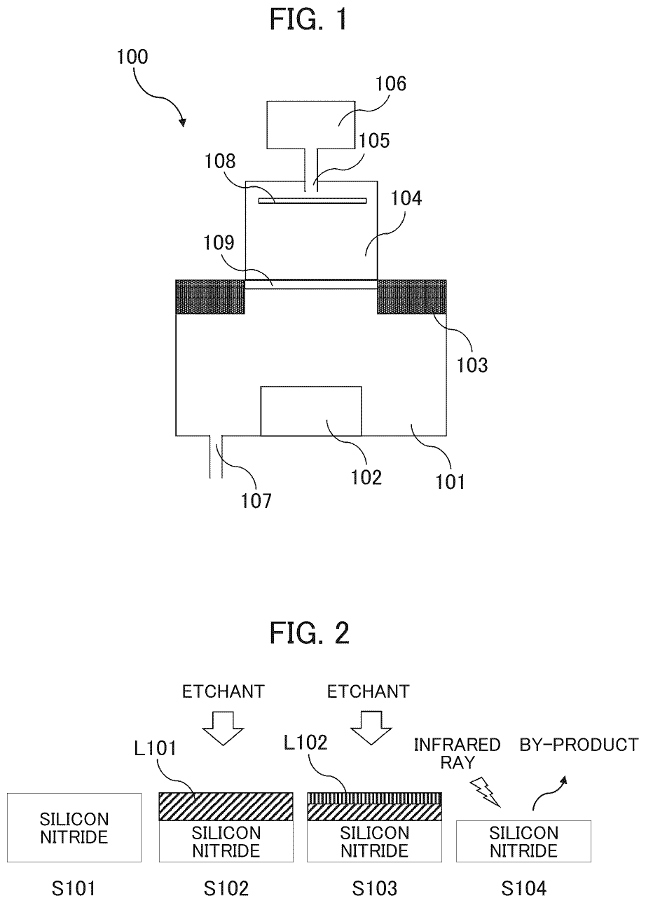

Using FIGS. 1 to 8, a description will be given of the first embodiment. The present embodiment uses a reactive species generated from a plasma of a H₂ gas and a plasma of a SF₆ gas and infrared irradiation to etch silicon nitride.

FIG. 1 is a cross-sectional view illustrating an outline of a configuration of an etching apparatus 100 according to the present embodiment. The present etching apparatus 100 includes a wafer stage 102 provided in a processing chamber 101, an infrared lamp 103 installed over the wafer stage 102 in the processing chamber 101, a plasma source 104 disposed over the wafer stage 102, a gas introduction unit 105 installed over the plasma source 104, a gas supply unit 106 that supplies gas into the gas introduction unit 105, a gas exhaust unit 107 that exhausts the gas in the processing chamber 101 therefrom, and a control unit not illustrated in FIG. 1.

An infrared ray to be applied to a wafer (sample) on the wafer stage 102 is required to vibrationally excite HF and etch silicon nitride as will be described later, and accordingly a light source capable of supplying a sufficient amount of the ray to vibrationally excite the HF to the wafer stage needs to be disposed to output the ray. In addition, since heating of the wafer contributes to removal of a by-product resulting from etching, such as ammonium silicate, ammonium, or silicon fluoride, it is desirable to have a heating mechanism. It is also possible to cause the infrared lamp 103 to function as a heating mechanism that heats the wafer placed on the wafer stage 102.

The gas supply unit 106 has an ability to selectively supply a gas containing hydrogen, a gas containing fluorine, and a gas containing both the hydrogen and the fluorine such as the HF. Examples of the gas (etchant) containing hydrogen include H₂, HCl, HF, H₂O, NH₃, CH₄, and the like. Examples of the gas (etchant) containing fluorine include SF₆, CF₄, CHF₃, CH₂F₂, CH₃F, C₂F₆, C₄F₉, NF₃, and the like. It is desirable that the gas supply unit 106 also has an ability to supply a reducing gas, such as BCl₃, and an ability to supply an inert gas capable of dilution, such as argon or nitrogen.

In the processing chamber 101, a gas dispersion plate 108 that disperses the gas introduced from the gas introduction unit 105 can be disposed. Alternatively, it may also be possible to dispose, between the plasma source 104 and the wafer stage 102, a shield plate 109 that controls respective amounts and distributions of the introduced gas and ions and radicals each generated from the plasma source 104. It may also be possible to further provide an adjustment mechanism that adjusts a pressure in the processing chamber 101 or a distance between the plasma source 104 and the wafer stage 102 so as to prevent the ions from being supplied to the wafer. To cool a wafer (semiconductor substrate) to be placed on an upper surface thereof, the wafer stage 102 preferably includes a mechanism that supplies a helium gas to a back surface of the wafer and a cooling mechanism that cools the wafer stage 102, such as a chiller.

Next, a description will be given of a specific example of silicon nitride etching. A schematic diagram illustrated in FIG. 2 illustrates a processing procedure in an etching method for a silicon nitride film according to the present embodiment, and shows changes in a wafer cross-sectional structure in individual steps of this etching. The progress of this processing procedure is controlled by the control unit of the etching apparatus 100.

First, in Step S101, a wafer having a surface at which silicon nitride is exposed is placed on the wafer stage 102. In Step S102 (first step), an etchant containing hydrogen is supplied from the gas supply unit 106 into the processing chamber 101 via the gas introduction unit 105 and applied to the silicon nitride of the wafer to form a modified layer (first modified layer) L101 in which hydrogen is bonded to the silicon nitride at the surface thereof. In Step S103 (second step), an etchant containing fluorine is applied to the silicon nitride via the gas introduction unit 105 to form a modified layer (second modified layer) L102 in which hydrogen and fluorine are bonded to the silicon nitride at an outermost surface thereof.

In Step S103, when the etchant contains hydrogen, fluorine is consumed under a scavenger effect and it becomes difficult to supply a sufficient amount of the fluorine to the silicon nitride, and therefore it is desirable that the etchant contains no hydrogen. In the present embodiment, radicals are supplied as the etchant but, even when a form in which the etchant is supplied is a gas or ions, the effect remains unchanged. When ions or radicals are used as the etchant, the ions or radicals are generated from the plasma source 104.

In Step S104 (third step), the modified layer L101 and the modified layer L102 that have been formed are irradiated with an infrared ray from the infrared lamp 103. This promotes vibrational excitation of the HF to cause etching of the silicon nitride film.

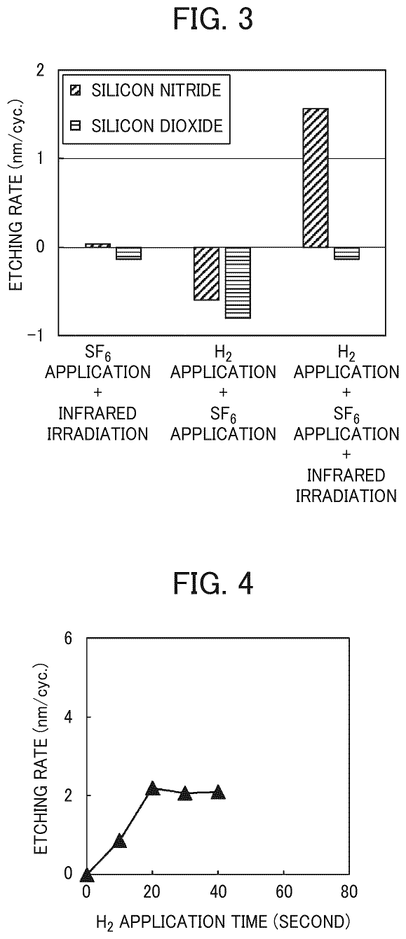

In FIG. 3, as a specific example, results of etching a single-layer film of silicon nitride and a single-layer film of silicon dioxide by using radicals resulting from a H₂ gas plasma, radicals resulting from a SH₆ gas plasma, and infrared irradiation are illustrated to be compared to each other. In FIG. 3, as a positive value of an etching rate is larger, etching is more advanced.

From the results in FIG. 3, it will be understood that, in the absence of an application of the H₂ gas plasma corresponding to Step S102 or in the absence of the infrared irradiation corresponding to Step S104, the etching of the silicon nitride film scarcely occurs. Meanwhile, it will be understood that, when each of Steps S102, S103, and S104 is present, the silicon nitride film is remarkably etched. Additionally, in either case, there is no etching of the silicon dioxide film. From the foregoing results, it will be understood that, to etch the silicon nitride film, Step S102, S103, and S104 are required.

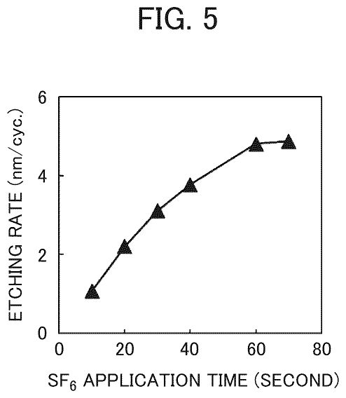

In FIGS. 4 and 5, a relationship between a H₂ gas plasma application time and an etching rate of the silicon nitride film and a relationship between a SF_{b} gas plasma application time and an etching rate of the silicon nitride film are respectively illustrated. It will be understood that, in either case, so-called self-saturation such that, when the application time is elongated, the etching rate is saturated is observed. When FIGS. 4 and 5 are compared to each other, the SF_{b} gas plasma has the longer application time until the self-saturation is observed. This may be conceivably because a hydrogen atom has an atomic radius smaller than that of a fluorine atom, and has consequently reached a deeper portion in the sample.

According to the present embodiment, through Steps S102 and S103, the modified layer L102 containing hydrogen and fluorine is formed at the outermost surface of the sample, and the modified layer L101 containing only hydrogen is formed immediately below the modified layer L102. It will be understood that, by irradiating a structure of the modified layers with an infrared ray in Step S104, the silicon nitride layer is etched.

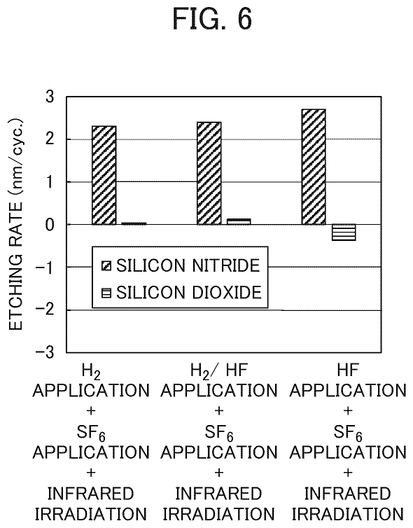

FIG. 6 illustrates respective etching rates of the silicon nitride film when the gas species was changed in Step S102. Even when HF is introduced as the gas instead of H₂, the silicon nitride film is etched. From the foregoing results, it will be understood that the etchant to be introduced in Step S102 is appropriate as long as at least hydrogen is contained therein.

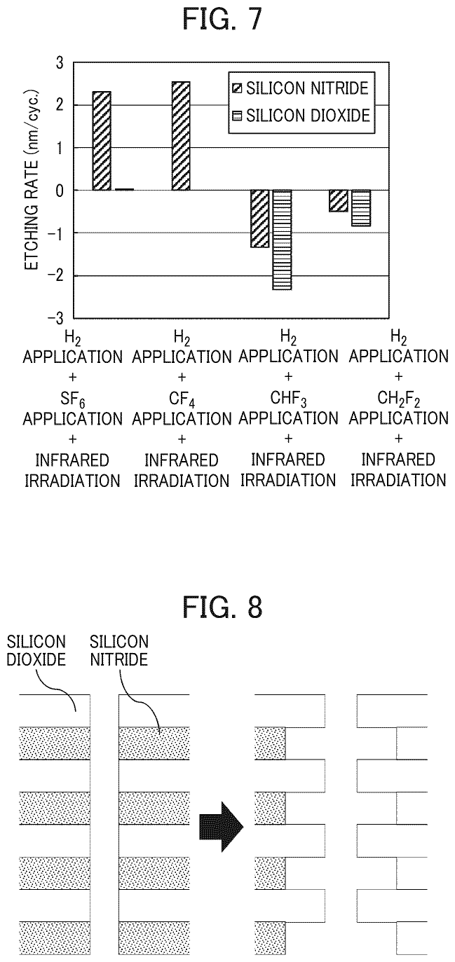

FIG. 7 illustrates respective etching rates of the silicon nitride film when the gas species was changed in Step S103. Even when CF₄ is introduced as the gas instead of SFr, the silicon nitride film is etched. Meanwhile, when CHF₃ or CH₂F₂ is introduced, the silicon nitride film is not etched. From the foregoing results, it will be understood that the etchant to be introduced in Step S103 is appropriate as long as fluorine is contained therein, but it is not desirable that the etchant contains hydrogen. It may also be possible that, in Step S103, an etchant containing nitrogen is supplied to the wafer simultaneously with the supply of the etchant containing fluorine.

As is obvious from the foregoing, the etching method according to the present embodiment has a high selectivity to the silicon dioxide film. Therefore, providing an additional step for removing an initial oxide film such as a natural oxide film between Steps S101 and S102 and introducing a reducing etchant such as BCl₃ is also effective in increasing the etching rate. In addition, since the silicon nitride film contains nitrogen and nitrogen is more likely to move than silicon, it can be considered that introducing an etchant containing nitrogen, such as N₂ or NF₃, from which self-complexity can be expected, is effective in reducing roughness or the like.

Next, a description will be given of the etching of the silicon nitride in an actual device structure. The etching of the silicon nitride, particularly highly selective isotropic etching to be performed on the silicon dioxide film, is expected to be applied to a step of removing dummy word lines or the like.

FIG. 8 illustrates a schematic diagram of the device structure. Silicon nitride layers and silicon dioxide layers are alternately stacked and, by using a gas and radicals as an etchant in the present invention, it is possible to selectively etch only the silicon nitride in a lateral direction without etching the silicon dioxide. In addition, according to the method in the present embodiment, the modified layers having the self-saturation are formed as described above, and therefore it is possible to achieve equal etching amounts above and below a hole. Moreover, by controlling thicknesses of the modified layers or the like by varying an etching time and an etchant amount, it becomes also possible to precisely control the etching amount.

### Second Embodiment

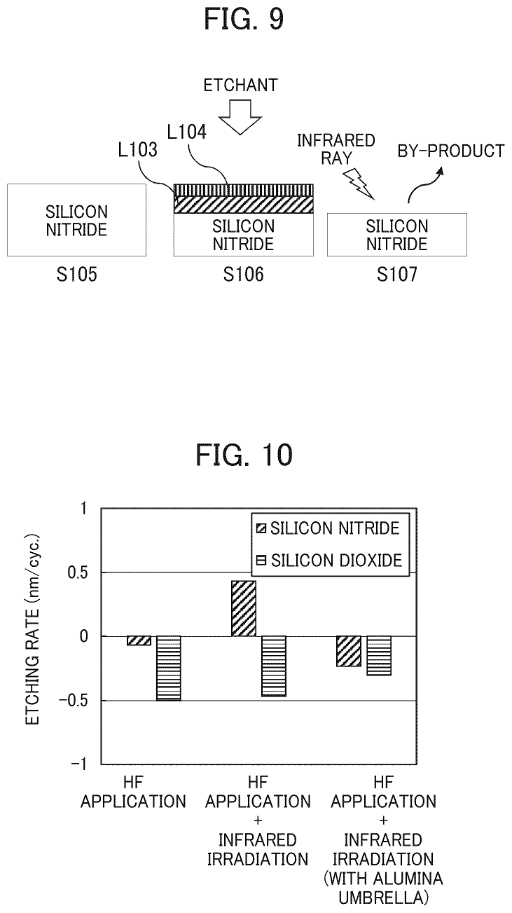

Using FIGS. 9 to 12, a description will be given of the second embodiment. The present embodiment relates to an example in which, using a reactive species generated from a plasma of a HF gas and infrared irradiation, silicon nitride is etched. In the present embodiment also, the etching can be performed using the etching apparatus illustrated in FIG. 1.

A schematic diagram illustrated in FIG. 9 illustrates a processing procedure in an etching method for a silicon nitride film, and shows a change in a wafer cross-sectional structure in each of steps of this etching. The progress of this processing procedure is controlled by the control unit of the etching apparatus 100.

In Step S105, a wafer having a surface at which the silicon nitride is exposed is placed on the wafer stage 102. In Step S106, an etchant containing HF is applied from the gas introduction unit 105 to the silicon nitride. Since a hydrogen atom has an atomic radius smaller than that of a fluorine atom, and consequently reaches a deeper portion in a sample, in the same manner as in the first embodiment, a modified layer L104 (first modified layer) containing hydrogen and fluorine is formed in an outermost surface, and a modified layer L103 (second modified layer) containing hydrogen is formed immediately below the modified layer L104.

In the present embodiment, radicals are supplied as the etchant but, even when a form in which the etchant is supplied is a gas or ions, the effect remains unchanged. When ions or radicals are used as the etchant, the ions or radicals are generated from the plasma source 104.

In Step S107, an infrared ray is applied from the infrared lamp 103 to the modified layer L103 and the modified layer L104 that have been formed to promote vibrational excitation of HF. As a result, a silicon nitride film is etched.

In FIG. 10, as a specific example, results of etching a single-layer film of silicon nitride and a single-layer film of silicon dioxide by using radicals resulting from a HF gas plasma and infrared irradiation are illustrated to be compared to each other. In FIG. 10, as a positive value of an etching rate is larger, etching is more advanced. At this time, each of the single-layer films was about 2 cm square, and placed on a 300 mm silicon substrate.

From the results in FIG. 10, it will be understood that, when there is no infrared irradiation corresponding to Step S107, the silicon nitride film is not etched. Meanwhile, it will be understood that, when each of Steps S106 and S107 was executed, the silicon nitride film was etched and, in either case, the silicon dioxide film was not etched.

From the foregoing results, it will be understood that, to etch the silicon nitride film, Steps S106 and S107 are required. It will also be understood that, even when infrared irradiation is performed simultaneously with the application of the plasma of the HF gas, the silicon nitride film is etched and therefore, to etch the silicon nitride, the infrared irradiation may be performed simultaneously with the supply of the etchant.

The etching method that simultaneously performs the infrared irradiation described above is applicable not only to the cycle etching described heretofore, but also to continuous etching. Meanwhile, when an umbrella made of an alumina base material that does not transmit an infrared ray is placed on the silicon nitride film to provide a state where the infrared ray is not directly applied only to the sample, the silicon nitride film is not etched (see FIG. 10). It can be considered that, since the silicon substrate is irradiated with the infrared ray, a temperature thereof is increased to also heat the sample, and therefore it will be understood that the silicon nitride film is etched not by the increased temperature, but by the infrared irradiation. It is also considered that, due to the placed alumina umbrella, the infrared ray is not directly applied but, under the effect of reflection or the like, only a small amount of the infrared ray is applied.

From the foregoing result, it will be understood that the infrared irradiation is required to drive the vibrational excitation of HF and, for appropriate driving, infrared irradiation of a given intensity or higher is required. Therefore, adjustment of the distance between the wafer stage 102 and the infrared lamp 103 or of a luminous intensity of the infrared lamp 103 is important.

Next, a description will be given of etching of silicon nitride in a real device structure. The etching of the silicon nitride, particularly atomic-layer-level etching that allows precise control of an etching amount, is also applicable to a trimming step of planarizing sidewall portions of the device.

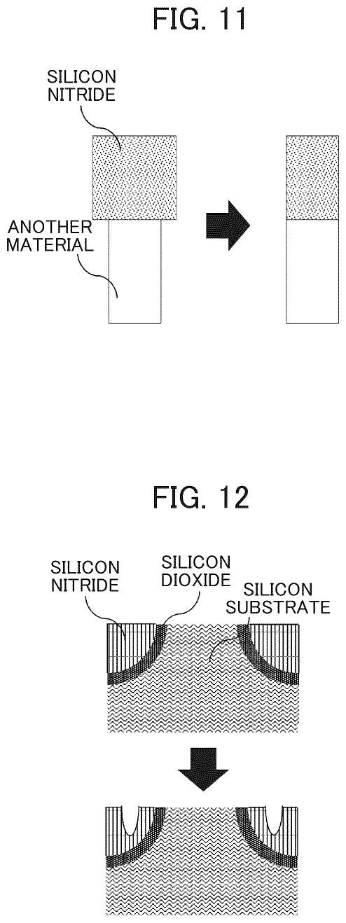

FIG. 11 illustrates a schematic diagram of the device. By using a gas or radicals as an etchant in the present embodiment in a device configuration in which the silicon nitride remains in a structure protruding from a different-species material in the previous step, it is possible to selectively etch only the silicon nitride in a lateral direction without etching the different-species material. In addition, by using ions in the present embodiment, it is also possible to anisotropically etch the silicon nitride.

FIG. 12 illustrates a schematic diagram of anisotropic etching of a source and a drain each made of silicon nitride in a DRAM. When the ions are used in the present embodiment, the modified layer L103 and the modified layer L104 are formed only over the silicon nitride, not on side walls of the silicon nitride, and consequently the silicon nitride film can anisotropically be etched.

According to the present invention, by forming the modified layer containing hydrogen and the modified layer containing hydrogen and fluorine on the silicon nitride film and then performing the infrared irradiation, it is possible to supply a sufficient amount of vibrationally excited HF to the silicon nitride film. As a result, it is possible to provide a technology that allows etching processing of the silicon nitride film to be performed at a high etching rate, while maintaining high processing dimension controllability at an atomic layer level, high uniformity in a pattern depth direction, and high selectivity to silicon dioxide.

### LIST OF REFERENCE SIGNS

100 Etching apparatus
101 Processing chamber 101
102 Wafer stage (cooling device)
103 Infrared lamp (irradiation device)
104 Plasma source
105 Gas introduction unit
106 Gas supply unit
107 Gas exhaust unit (exhaust device)
108 Gas dispersion plate
109 Shield plate (perforated blocking plate for blocking ions)

1. An etching method comprising:
a first step of supplying an etchant containing hydrogen to a sample having a surface at which a silicon nitride is exposed to form a first modified layer in which the hydrogen is bonded to the silicon nitride;
a second step of supplying an etchant containing fluorine to the sample to form, over the first modified layer, a second modified layer in which the hydrogen and the fluorine are bonded to the silicon nitride; and
a third step of irradiating the first modified layer and the second modified layer with an infrared ray.

2. An etching method comprising:
supplying an etchant containing a hydrogen fluoride to a sample having a surface at which a silicon nitride is exposed to form a first modified layer in which hydrogen is bonded to the silicon nitride and a second modified layer in which the hydrogen and fluorine are bonded to the silicon nitride; and
irradiating the first modified layer and the second modified layer with an infrared ray.

3. The etching method according to claim 2, wherein, simultaneously with the supply of the etchant containing the hydrogen fluoride, the sample is irradiated with the infrared ray.

4. The etching method according to claim 1, wherein, in the second step, an etchant containing nitrogen is supplied to the sample simultaneous with the supply of the etchant containing the fluorine.

5. The etching method according to claim 1, wherein, in the third step, the first modified layer and the second modified layer are heated, while being simultaneously irradiated with the infrared ray.

6. The etching method according to claim 1, further comprising, before the first step:
a step of removing an initial oxide film from over the sample.

7. An etching apparatus that implements the etching method according to claim 1, the apparatus comprising:
a processing chamber that contains the sample;
a gas supply unit that individually supplies, into the processing chamber, a gas containing hydrogen and a gas containing fluorine;
an exhaust device that exhausts an inside of the processing chamber;
an irradiation device that irradiates the sample with an infrared ray; and
a cooling device that cools the sample.

8. The etching apparatus according to claim 7, wherein the gas supply unit supplies a hydrogen fluoride into the processing chamber.

9. The etching apparatus according to claim 7, wherein a plasma source is provided in the processing chamber to generate an ion or a radical from the gas.

10. The etching apparatus according to claim 9, wherein a porous blocking plate for blocking the ion is disposed between the plasma source and the sample.

11. An etching apparatus according to claim 9, comprising:
an adjustment mechanism capable of adjusting a pressure in the processing chamber or a distance between the plasma source and the sample.

12. An etching apparatus that implements the etching method according to claim 2, the apparatus comprising:
a processing chamber that contains the sample;
a gas supply unit that supplies, into the processing chamber, a gas containing a hydrogen fluoride;
an exhaust device that exhausts an inside of the processing chamber;
an irradiation device that irradiates the sample with an infrared ray; and
a cooling device that cools the sample.
